(19) United States
(12) Patent Application Publication
(10) Pub. No.: US 2026/0040984 A1
(43) Pub. Date: Feb. 5, 2026

(54) WAFER BONDING WITH ENHANCED THERMAL DISSIPATION

(71) Applicant: Taiwan Semiconductor Manufacturing Company, Ltd., Hsinchu (TW)

(72) Inventors: Zheng-Yong LIANG, Kaohsiung City (TW); Yu-Yun PENG, Hsinchu (TW); Keng-Chu LIN, Chao-Chou (TW); Wei-Ting YEH, Hsinchu City (TW); Yi-Chien WANG, Hsinchu City (TW)

(73) Assignee: Taiwan Semiconductor Manufacturing Company, Ltd., Hsinchu (TW)

(21) Appl. No.: 18/794,585

(22) Filed: Aug. 5, 2024

(51) Int. Cl. H01L 23/00

(52) U.S. Cl. CPC H01L 24/83; H01L 24/27; H01L 24/29; H01L 24/32; H01L 2224/2743; H01L 2224/29084; H01L 2224/29166; H01L 2224/29188; H01L 2224/32221; H01L 2224/325; H01L 2224/83193; H01L 2224/83948

(57) ABSTRACT

The present disclosure describes a bonded semiconductor structure and a method of forming the bonded semiconductor structure. The bonded semiconductor structure includes first and second substrates bonded with a bonding structure. The bonding structure provides high thermal conductivity and high bonding strength between the first and second substrates. The bonding structure includes bonding layers and adhesion layers, with the bonding layers including titanium oxide and the adhesion layers including titanium nitride. The method includes forming a first adhesion layer on the first substrate and a second adhesion layer on the second substrate. The method also includes forming a first bonding layer on the first adhesion layer and a second bonding layer on the second adhesion layer. The method further includes bonding the first and second substrates by bonding the first and second bonding layers together.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAAFETs). Such scaling down allows more semiconductor devices to be integrated into a given area but increases the complexity of semiconductor manufacturing processes. Semiconductor devices can be stacked vertically to scale down the dimensions, increase performance, and reduce cost. Wafer bonding is a technique to stack the semiconductor devices together.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1A illustrates a bonded structure having a first substrate bonded to a second substrate, in accordance with some embodiments.

FIG. 1B illustrates a bonded structure having multiple substrates bonded together, in accordance with some embodiments.

FIGS. 2A and 2B illustrate bonding layers in a bonded structure, in accordance with some embodiments.

FIG. 3 is a flow diagram of a method for bonding a first substrate to a second substrate, in accordance with some embodiments.

FIGS. 4, 5A, 5B, and 6 illustrate a bonded structure having a first substrate bonded to a second substrate at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

With the continuous scaling down of semiconductor devices, three-dimensional (3D) integrated circuits (ICs) are developed to resolve the limitations of the number and length of interconnections between semiconductor devices as the number of semiconductor devices increases. The development of 3D IC requires improvements of wafer bonding. In wafer bonding, two semiconductor substrates, such as semiconductor wafers, are bonded together to form a bonded structure without the need for an intervening substrate or device. One semiconductor substrate can be a carrier substrate, and the other semiconductor substrate can be a device substrate having semiconductor devices. A bonding layer, such as silicon oxide, can be formed on each semiconductor substrate. One semiconductor substrate can be flipped and placed on top of the other semiconductor substrate, with the bonding layers of these two semiconductor substrates in contact. After a bonding anneal, silicon-oxygen-silicon (Si—O—Si) bonds can form at the interface of the bonding layers and can bond the two semiconductor substrates together. This bonding process can be referred to as “wafer fusion bonding.” The bond strength of the wafer fusion bonding can be sufficient to be compatible with subsequent semiconductor manufacturing processes.

With the scaling down of the dimensions of semiconductor devices, more semiconductor devices are integrated into given areas on the device substrate, posing increasing challenges related to efficient heat dissipation. In the bonded structure, heat generated by the semiconductor devices on the device substrate can transfer through the bonding layer and dissipated to the carrier substrate. Thinning the bonding layer can facilitate better heat dissipation. However, due to its relatively low thermal conductivity at about 1 W/m·K, silicon oxide as the material of bonding layer becomes a bottleneck of improving heat dissipation. As semiconductor devices continue to evolve, it is critical to provide wafer bonding with new designs of bonding layers or bonding structures with materials having higher thermal conductivities while providing adequate bond strengths and being compatible with the underlying materials in the device substrate and the carrier substrate and the subsequent semiconductor manufacturing processes.

To overcome the challenges mentioned above, the embodiments described herein are directed to a bonded semiconductor structure having first and second substrates bonded by a bonding structure and a method of forming the bonded structure. In some embodiments, the bonding structure can include multiple layers of titanium oxide and titanium nitride. In some embodiments, the method can include forming a first adhesion layer on the first substrate and a first bonding layer on the first adhesion layer. The method can also include forming a second adhesion layer on the second substrate and a second bonding layer on the second adhesion layer. The method can also include bonding the first and second substrates by bonding the first and second bonding layers together and annealing the bonded semiconductor structure.

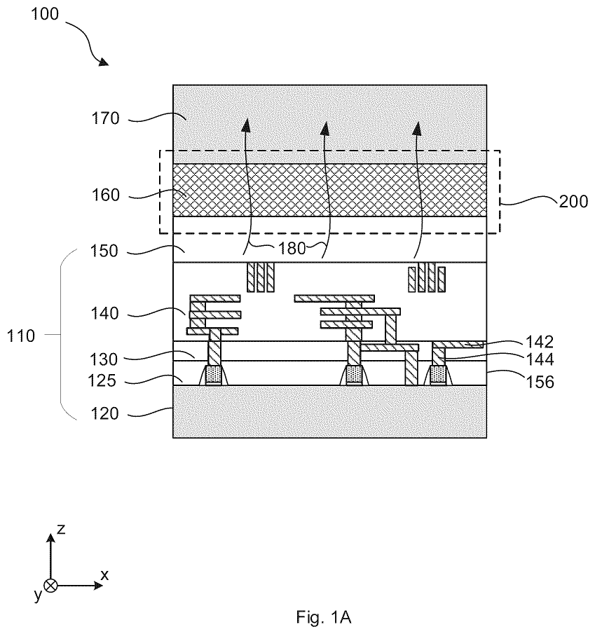

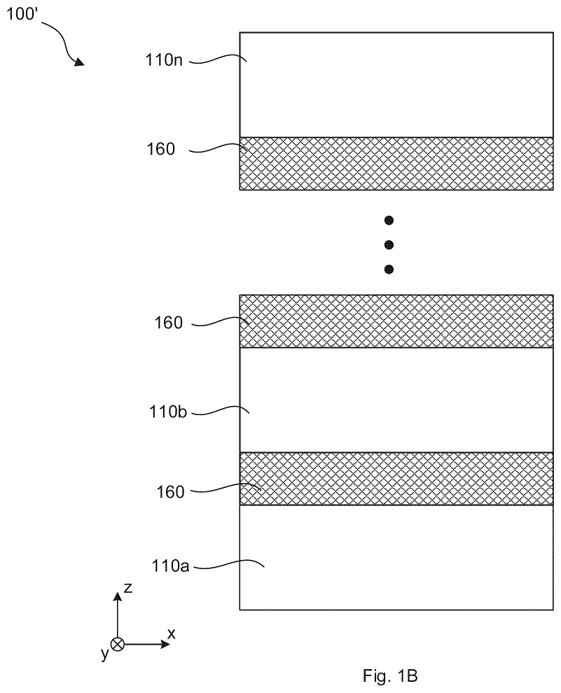

FIG. 1A illustrates a bonded structure 100 having a first substrate 110 bonded to a second substrate 170 by a bonding structure 160, in accordance with some embodiments. In some embodiments, first substrate 110 can be a device substrate having semiconductor devices 156 and second substrate 170 can be a carrier substrate, as shown in FIG. 1A. In some embodiments, the carrier substrate can be thinned down to a thickness less than about 775 μm. In some embodiments, the carrier substrate may not be thinned down.

Referring to FIG. 1A, first substrate 110 can include a semiconductor substrate 120, semiconductor devices 156 on semiconductor substrate 120, a middle-end-of-line (MEOL) layer 130 over semiconductor devices 156, a back-end-of-line (BEOL) layer 140 on MEOL layer 130, and a dielectric layer 150 on BEOL layer 140.

Substrate 120 can include a semiconductor material, such as silicon. In some embodiments, substrate 120 includes a crystalline silicon substrate (e.g., wafer). In some embodiments, substrate 120 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, gallium indium phosphide, gallium indium arsenide, gallium indium arsenic phosphide, aluminum indium arsenide, and/or aluminum gallium arsenide; (iv) a semiconductor on insulator including silicon on insulator (SOI); or (v) a combination thereof. Further, substrate 120 can be doped depending on design requirements (e.g., p-type substrate or n-type substrate). In some embodiments, substrate 120 can be doped with p-type dopants (e.g., boron, indium, aluminum, or gallium) or n-type dopants (e.g., phosphorus or arsenic).

In some embodiments, second substrate 170 can include a substrate having a semiconductor material similar to substrate 120. In some embodiments, second substrate 170 can have a semiconductor material the same as or different from the semiconductor material of substrate 120.

In some embodiments, semiconductor devices 156 can include MOSFETs, finFETs, and/or GAAFETs. As shown in FIG. 1A, semiconductor devices 156 can be disposed on semiconductor substrate 120. In some embodiments, an interlayer dielectric (ILD) 125 can be disposed on semiconductor devices 156. In some embodiments, MEOL layer 130 can include one or more layers of interconnect structures electrically coupled to semiconductor devices 156. The interconnect structures can include metal lines 142 and metal vias 144 embedded in a dielectric material. In some embodiments, BEOL layer 140 can also include interconnect structures similar to those in MEOL layer 130 and electrically coupling to semiconductor devices 156. In some embodiments, BEOL layer 140 can also include one or more layers of interconnect structures. For example, BEOL layer 140 can include 2, 4, 8, 12, or 16 layers of interconnect structures

Dielectric layer 150 can be an inter-layer dielectric (ILD) disposed over semiconductor devices 156. In some embodiments, dielectric layer 150 can include silicon nitride or silicon oxide. In some embodiments, dielectric layer 150 may affect a heat dissipation of semiconductor devices 156 and the interconnect structures in BEOL layer 140 and MEOL layer 130. In particular, a heat 180 generated by semiconductor devices 156, MEOL layer 130, and interconnect structures in BEOL layer 140 can diffuse into dielectric layer 150 and may further diffuse from dielectric layer 150 into second substrate 170 through bonding structure 160.

In some embodiments, bonded structure 100 with first and second substrates 110 and 170 bonded by bonding structure 160 can be extended to fusion bonding more than two substrates together. FIG. 1B illustrates a bonded structure 100′ having multiple substrates 110a-110n bonded together by a number of bonding structures 160, in accordance with some embodiments. The discussion of elements in FIG. 1A with the same annotations applies to FIG. 1B, unless mentioned otherwise. In some embodiments, each of substrates 110a-110n can be the same as or similar to first substrate 110 and/or second substrate 170 as shown in FIG. 1A.

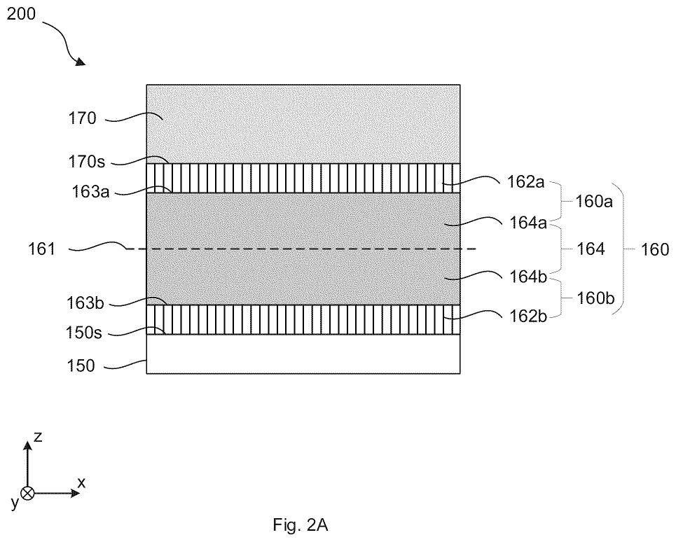

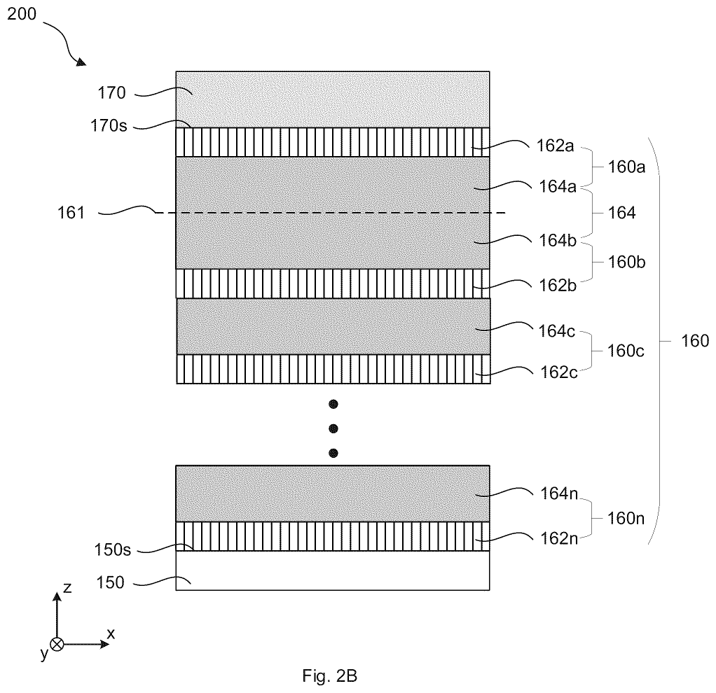

Referring back to FIG. 1A, a structure 200 can include bonding structure 160 and portions of second substrate 170 and dielectric layer 150 adjacent to bonding structure 160. FIGS. 2A and 2B illustrate structure 200 with additional details on bonding structure 160, according to some embodiments. The description of elements in FIG. 1A with the same annotations applies to FIGS. 2A and 2B, unless mentioned otherwise.

Referring to FIG. 2A, bonding structure 160 can include adhesion layers 162a and 162b, with adhesion layer 162a in contact with second substrate 170 and adhesion layer 162b in contact with dielectric layer 150. Bonding structure 160 can further include bonding layers 164a and 164b, with bonding layer 164a in contact with adhesion layer 162a and bonding layer 164b in contact with adhesion layer 162b.

In some embodiments, adhesion layers 162a and 162b can be titanium-based dielectric layers. For example, adhesion layers 162a and 162b can include titanium nitride (TiNₓ). In some embodiments, TiNₓ in adhesion layers 162a and 162b can provide strong adhesions between bonding layer 164a and second substrate 170 and between bonding layer 164b and dielectric layer 150, respectively. In some embodiments, a bonding strength of adhesion layers 162a and 162b can be greater than about 1.6 J/m². In some embodiments, adhesion layers 162a and 162b can be formed on a surface 170s of second substrate 170 and a surface 150s of dielectric layer 150, respectively, by simultaneously depositing TiNₓ such that thicknesses of adhesion layers 162a and 162b can be substantially the same. In some embodiments, the thicknesses of adhesion layers 162a and 162b can be different. In some embodiments, the thicknesses of adhesion layers 162a and 162b can be between about 5 nm and about 15 nm. For example, the thicknesses of adhesion layers 162a and 162b can be about 10 nm. If the thicknesses of adhesion layers 162a and 162b are less than 5 nm, coverages of adhesion layers 162a and 162b on surfaces 170s and 150s may not be complete. If the thicknesses of adhesion layers 162a and 162b are greater than about 15 nm, adhesion layers 162a and 162b may be less dielectric, resulting in leakage current channels in adhesion layers 162a and 162b.

In some embodiments, a ratio of titanium (Ti) to nitrogen (N) elements in adhesion layers 162a and 162b can be about 1:1 (TiNₓ with x˜1). In some embodiments, a carbon concentration in adhesion layers 162a and 162b can be less than about 1%. In some embodiments, after the deposition of TiNₓ, adhesion layers 162a and 162b can be amorphous, and then after an annealing process, a crystal structure of adhesion layers 162a and 162b can be transformed into face-centered cubic (FCC). In some embodiments, a thermal conductivity of adhesion layers 162a and 162b can be between about 20 W/m·K and about 30 W/m·K. In some embodiments, the thermal conductivity of adhesion layers 162a and 162b can be greater than a thermal conductivity of the material included in dielectric layer 150, such as silicon oxide with a thermal conductivity of about 1 W/m. K. In some embodiments, the above range of thermal conductivity of adhesion layers 162a and 162b can facilitate effective diffusion of heat 180 generated by semiconductor devices 156 into second substrate 170, as shown in FIG. 1A. In some embodiments, the ratio of Ti to N elements in adhesion layers 162a and 162b being about 1:1 can promote the thermal conductivity of adhesion layers 162a and 162b. In some embodiments, the carbon concentration in adhesion layers 162a and 162b being less than about 1% can promote the thermal conductivity of adhesion layers 162a and 162b. In some embodiments, the crystal structure of adhesion layers 162a and 162b being FCC can promote the thermal conductivity of adhesion layers 162a and 162b.

In some embodiments, bonding layers 164a and 164b can be titanium-based dielectric layers. For example, bonding layers 164a and 164b can include titanium oxide (TiOₓ). In some embodiments, TiOₓ in bonding layers 164a and 164b can provide a strong bonding strength between bonding layer 164a and bonding layer 164b. In some embodiments, a bonding strength of bonding layers 164a and 164b can be greater than about 1.6 J/m2. In some embodiments, bonding layers 164a and 164b can be formed on adhesion layers 162a and 162b, respectively, by simultaneously depositing TiOₓ on a surface 163a of adhesion layers 162a and a surface 163b of adhesion layer 162b, respectively, such that thicknesses of bonding layers 164a and 164b can be substantially the same. Bonding layers 164a and 164b can be bonded together in a bonding process after the deposition of TiOₓ, with a bonding interface 161 as shown in FIG. 2A. In some embodiments, the thicknesses of bonding layers 164a and 164b can be different. In some embodiments, the thicknesses of bonding layers 164a and 164b can be between about 10 nm and about 80 nm. If the thicknesses of bonding layers 164a and 164b are less than 10 nm, coverages of bonding layers 164a and 164b on surfaces 163a and 163b may not be complete. If the thicknesses of bonding layers 164a and 164b are greater than 80 nm, it may take a long deposition time to deposit bonding layers 164a and 164b, lowering manufacturing efficiency. In some embodiments, a ratio of the thicknesses of adhesion layers 162a or 162b to the thicknesses of bonding layers 164a or 164b can be between about 0.2 and about 0.8.

In some embodiments, a ratio of titanium (Ti) to oxygen (O) elements in bonding layers 164a and 164b can be about 1:2 (TiOₓ with x˜2). In some embodiments, a carbon concentration in bonding layers 164a and 164b can be less than about 1%. In some embodiments, after the deposition of TiOₓ, bonding layers 164a and 164b can be amorphous, and after the annealing process following the bonding process, a crystal structure of bonding layers 164a and 164b can be transformed into tetragonal having a (101) crystal orientation along a direction perpendicular to surfaces 163a and 163b (e.g., the z-axis). For example, the crystal structure of bonding layers 164a and 164b can be anatase. In some embodiments, a thermal conductivity of bonding layers 164a and 164b can be between about 5 W/m·K and about 10 W/m·K. For example, the thermal conductivity of bonding layers 164a and 164b can be about 8.5 W/m·K. In some embodiments, the thermal conductivity of bonding layers 164a and 164b can be greater than a thermal conductivity of the material included in dielectric layer 150, such as silicon oxide. In some embodiments, the thermal conductivity of bonding layers 164a and 164b in the above range can facilitate effective diffusion of heat 180 generated by semiconductor devices 156 into second substrate 170, as shown in FIG. 1A. In some embodiments, the ratio of Ti and O elements in bonding layers 164a and 164b being about 1:2 can promote the thermal conductivity of bonding layers 164a and 164b and the bonding strength of bonding layers 164a and 164b. In some embodiments, the carbon concentration in bonding layers 164a and 164b being less than about 1% can promote the thermal conductivity of bonding layers 164a and 164b and the bonding strength of bonding layers 164a and 164b. In some embodiments, the crystal structure of bonding layers 164a and 164b being anatase can promote the thermal conductivity of bonding layers 164a and 164b and the bonding strength of bonding layers 164a and 164b.

Adhesion layer 162a and bonding layer 164a can compose a bilayer structure 160a, and adhesion layer 162b, and bonding layer 164b can compose a bilayer structure 160b. Such bilayer structures including an adhesion layer and a bonding layer in structure 200 can facilitate a strong bonding between first substrate 110 and second substrate 170 due to the high bonding strength provided TiOₓ in bonding layers 164a and 164b, while TiNₓ in adhesion layers 162a and 162b can provide strong adhesion between bonding layer 164a and second substrate 170 and between bonding layer 164b and dielectric layer 150, respectively. Without adhesion layers 162a and 162b, a direct deposition of TiOₓ on surface 170s and 150s may result in defects at interfaces between bonding layer 164a and second substrate 170 and between bonding layer 164b and dielectric layer 150. The presence of adhesion layers 162a and 162b can be beneficial for fabricating defect-free interfaces. In some embodiments, the presence of adhesion layers 162a and 162b can also improve a quality of bonding layers 164a and 164b. For example, adhesion layers 162a and 162b can have a roughness at surfaces 163a and 163b to be less than about 10 Å, which can support the deposition of uniform and defect-free bonding layers 164a and 164b. In some embodiments, after the bonding process of bonding layers 164a and 164b, a roughness of bonding interface 161 can be less than about 10 Å. In some embodiments, after the annealing process, defects at bonding interface 161 formed after the bonding process can be removed as the crystal structure of bonding layers 164a and 164b is transformed from amorphous to anatase, such that bonding layers 164a and 164b can be considered as a whole bonding layer 164, as shown in FIG. 2A. In some embodiments, bonding structure 160 including bonding layer 164 and adhesion layers 162a and 162b can have an overall thermal conductivity between about 5 W/m. K and about 20 W/m·K.

FIG. 2B illustrates another embodiment of structure 200 as shown in FIG. 1A, with additional details on bonding structure 160. The description of elements in FIGS. 1 and 2A with the same annotations applies to FIG. 2B, unless mentioned otherwise.

Referring to FIG. 2B, bonding structure 160 can include one bilayer structure 160a formed on surface 170s of second substrate 170, similar to the structure in FIG. 2A. However, instead of forming only one bilayer structure 160b on surface 150s of dielectric layer 150 as shown in FIG. 2A, bonding structure 160 in FIG. 2B can include a stack of bilayer structures 160b-160n formed on surface 150s of dielectric layer 150. In some embodiments, the number of bilayer structures in the stack of bilayer structures 160b-160n can be between about 2 and about 20. In some embodiments, bonding layers 164c-164n can be the same as or similar to bonding layers 164a and/or 164b, in terms of their thickness, crystal structure, ratios of chemical element, thermal conductivity, surface roughness, and carbon concentration. In some embodiments, bonding layers 164c-164n can be different from bonding layers 164a and/or 164b, for example, with different thicknesses. In some embodiments, adhesion layers 162c-162n can be the same as or similar to adhesion layers 162a and/or 162b, in terms of their thicknesses, crystal structures, ratios of chemical elements, thermal conductivities, surface roughness, and carbon concentrations. In some embodiments, adhesion layers 162c-162n can be different from adhesion layers 162a and/or 162b, for example, with different thicknesses. In some embodiments, bonding layer 164, as formed by bonding together bonding layers 164a and 164b, is a topmost bonding layer in bonding structure 160, with respect to the rest of bonding layers 164c-164n. In some embodiments, a thickness of bonding layer 164 can be greater than the thicknesses of bonding layers 164c-164n. In some embodiments, a ratio of the thickness of bonding layer 164 to the thicknesses of bonding layers 164c-164n can be about 2:1.

In some embodiments, as shown in FIG. 2B, by including multiple adhesion layers 162c-162n with their thermal conductivities between about 20 W/m·K and about 30 W/m·K, the stack of bilayer structures 160b-160n can improve an overall thermal conductivity of bonding structure 160. In some embodiments, bonding structure 160 including bilayer structure 160a and the stack of bilayer structures 160b-160n can have the overall thermal conductivity between about 15 W/m·K and about 25 W/m·K. In some embodiments, including multiple adhesion layers 162c-162n can also improve a condition of roughness in bonding structure 160. For example, roughness of interfaces in bonding structure 160 as shown in FIG. 2B can be less than about 5 Å.

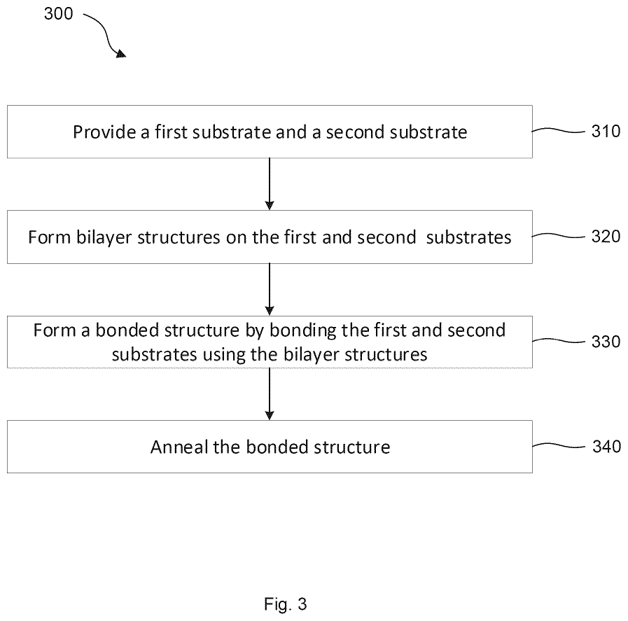

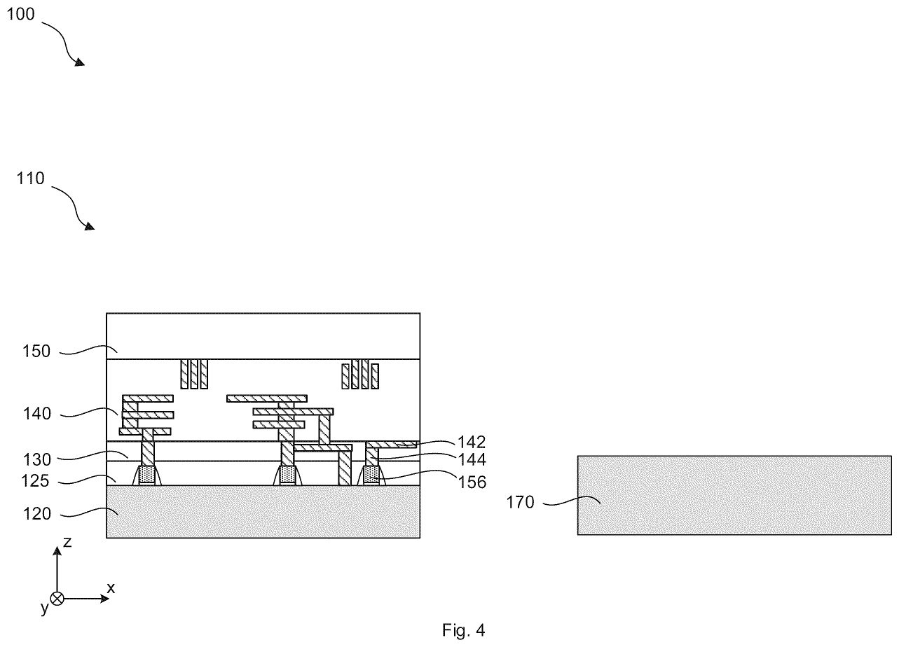

According to some embodiments, FIG. 3 illustrates a flowchart of a method 300 for forming bonded structure 100 as shown in FIG. 1A with bonding structures 160 as shown in FIGS. 2A and 2B. This disclosure is not limited to this operational description and additional operations may be performed. Other operations can be performed between the various operations of method 300 and are omitted merely for clarity. Moreover, not all operations may be needed to perform the disclosure provided herein. Additionally, some of the operations may be performed simultaneously, or in a different order than the ones shown in FIG. 3. In some embodiments, one or more other operations may be performed in addition to or in place of the presently described operations. For illustrative purposes, method 300 is described with reference to intermediate structures shown in FIGS. 4, 5A, 5B, and 6. The discussion of elements in FIGS. 1A-2B with the same annotations applies to FIGS. 4, 5A, 5B, and 6, unless mentioned otherwise.

Referring to FIG. 3, method 300 begins with operation 310, in which a first substrate and a second substrate are provided, as described with reference to FIG. 4, which illustrates a partially-fabricated structure 100. In some embodiments, the first substrate can be a device substrate including semiconductor devices 156, semiconductor substrate 120, MEOL layer 130, BEOL layer 140, and dielectric layer 150. In some embodiments, the second substrate can be carrier substrate 170. In some embodiments, providing the first substrate can include forming semiconductor devices 156 on substrate 120, forming MEOL layer 130 and BEOL layer 140 on semiconductor devices 156 with interconnect structures (e.g., metal lines 142 and metal vias 144) embedded in MEOL layer 130 and BEOL layer 140, and forming dielectric layer 150 on semiconductor devices 156. The fabrication operations to form semiconductor devices 156, MEOL layer 130, BEOL layer 140, and dielectric layer 150 are not described in detail for case of description.

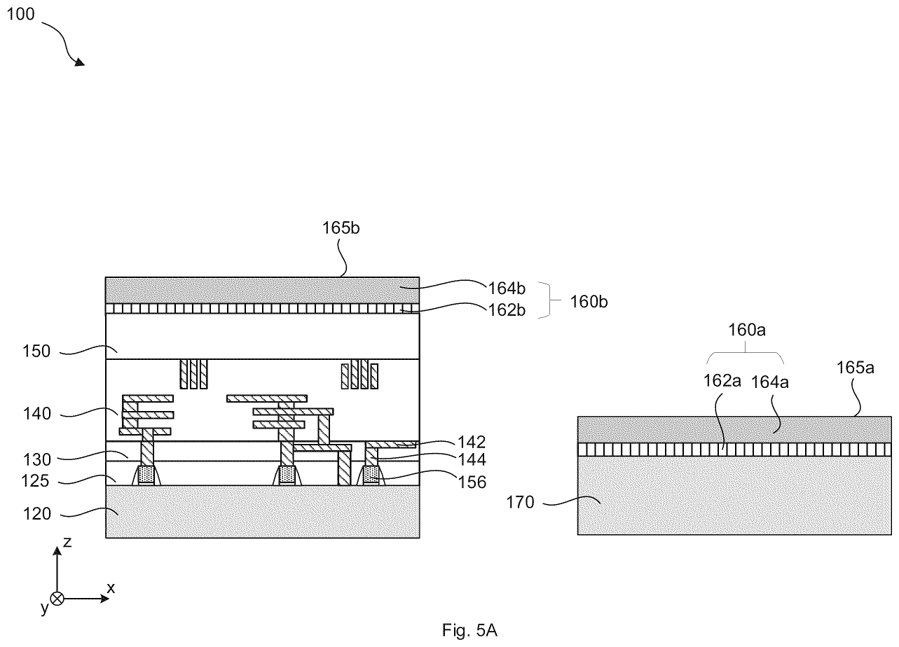

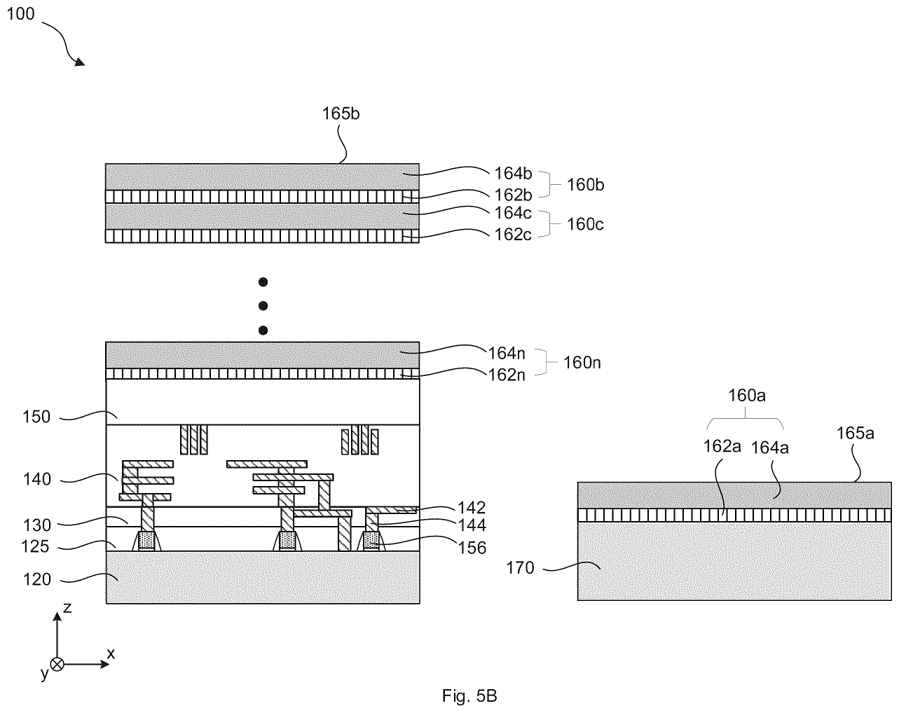

Referring to FIG. 3, method 300 continues with operation 320, in which bilayer structures are formed on the first and second substrates, as described with reference to FIG. 5A, according to some embodiments. Bilayer structure 160a can be formed on second substrate 170, and bilayer structure 160b can be formed on dielectric layer 150 of first substrate 110.

In some embodiments, forming bilayer structure 160a can include depositing adhesion layer 162a on second substrate 170, followed by depositing bonding layer 164a on adhesion layer 162a, as described with reference to FIG. 5A. In some embodiments, adhesion layer 162a and bonding layer 164a can be deposited by chemical vapor deposition (CVD), plasma-enhanced CVD (PECVD), atomic layer deposition (ALD), physical vapor deposition (PVD), high density plasma (HDP), flowable chemical vapor deposition (FCVD), or other suitable deposition methods, and/or combinations thereof.

Adhesion layer 162a can be formed by depositing TiNₓ in a deposition chamber. In some embodiments, parameters of the deposition environment can be controlled to control properties of adhesion layer 162a. In some embodiments, a deposition temperature of adhesion layer 162a can be between about 70° C. and about 250° C. In some embodiments, a deposition time and/or a deposition rate can be controlled to deposit adhesion layer 162a with a thickness between about 5 nm and about 15 nm. In some embodiments, the deposition rate, a deposition pressure, and/or the deposition temperature can be controlled to control a roughness of adhesion layer 162a to be less than about 10 Å. In some embodiments, the deposition rate and the deposition temperature can be controlled to deposit adhesion layer 162a with an amorphous structure. In some embodiments, precursors for depositing TiNₓ can be controlled to deposit adhesion layer 162a with a ratio of Ti to N elements to be about 1:1. In some embodiments, purities of the precursors and/or the deposition environment can be controlled to limit a carbon concentration in adhesion layer 162a to be less than about 1%.

Bonding layer 164a can be formed by depositing TiOₓ in the same deposition chamber or in a different deposition chamber. In some embodiments, parameters of the deposition environment can be controlled to control properties of bonding layer 164a. In some embodiments, a deposition temperature of bonding layer 164a can be between about 70° C. and about 250° C. In some embodiments, a deposition time and/or a deposition rate can be controlled to deposit bonding layer 164a with a thickness between about 10 nm and about 80 nm. In some embodiments, the deposition rate, a deposition pressure, and/or the deposition temperature can be controlled to control a roughness of bonding layer 164a to be less than about 10 Å. In some embodiments, the deposition rate and the deposition temperature can be controlled to deposit bonding layer 164a with an amorphous structure. In some embodiments, precursors for depositing TiOₓ can be controlled to deposit bonding layer 164a with a ratio of Ti to O elements to be about 1:2. In some embodiments, purities of the precursors and/or the deposition environment can be controlled to limit a carbon concentration in bonding layer 164a to be less than about 1%.

In some embodiments, depositing adhesion layer 162b and bonding layer 164b can be the same as or similar to depositing adhesion layer 162a and bonding layer 164a, respectively. The deposition of adhesion layers 162a and 162b and bonding layers 164a and 164b can be perform with first substrate 110 and second substrate 170 placed within the same deposition chamber. In some embodiments, adhesion layers 162a and 162b can be deposited simultaneously, and bonding layers 164a and 164b can be deposited simultaneously, such that the properties of bilayer structures 160a and 160b can be consistent for both first substrate 110 and second substrate 170, and the deposition process can be more efficient than forming bilayer structures 160a and 160b sequentially. Bilayer structures 160a and 160b include top surfaces 165a and 165b, respectively. In a subsequent bonding process, bilayer structures 160a and 160b can be bonded with top surfaces 165a and 165b pressed against each other.

In some embodiments, more than one bilayer structure can be formed on the first substrate, as described with reference to FIG. 5B, which illustrates that bilayer structure 160a can be formed on second substrate 170, and the stack of bilayer structures 160b-160n can be formed on dielectric layer 150 of first substrate 110. The description of elements in FIG. 5A with the same annotations applies to FIG. 5B, unless mentioned otherwise.

In some embodiments, forming each of bilayer structures 160c-160n can be the same as or similar to forming bilayer structure 160b. For example, forming adhesion layers 162c-162n can include depositing TiNₓ, and forming bonding layers 164c-164n can include depositing TiOₓ. In some embodiments, when depositing adhesion layers 162c-162n and bonding layers 164c-164n on dielectric layer 150, second substrate 170 can be covered by a shutter or temporarily transfer to a loading chamber next to the deposition chamber, so that second substrate 170 is not exposed to the precursors for deposition. In some embodiments, after bilayer structures 160c-160n are formed on first substrate 110, bilayer structure 160b can be formed on bilayer structure 160c, and bilayer structure 160a can be formed on second substrate 170, similar to the description with reference to FIG. 5A.

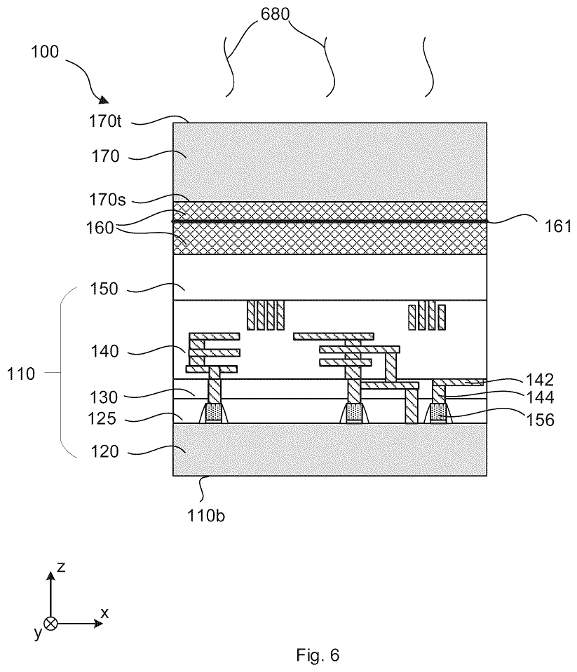

Referring to FIG. 3, method 300 continues with operation 330, in which the first and second substrates are bonded using the bilayer structures to form a bonded structure, as described with reference to FIG. 6, according to some embodiments. For example, a bonding process for bonding first substrate 110 and second substrate 170 can include stacking bonding layers 164a and 164b with top surfaces 165a and 165b facing each other to form bonded structure 100 with bonding interface 161, as described with reference to FIG. 6.

In some embodiments, parameters of the bonding process can be controlled to control a quality of bonding interface 161, such as to reduce an amount of defects at bonding interface 161, to improve a roughness condition of bonding interface 161, and to increase a bonding strength between bonding layers 164a and 164b at bonding interface 161. In some embodiments, the bonding process can be performed in a bonding chamber, in which each of first and second substrates 110 and 170 is held by a substrate holder and stacked with each other. In some embodiments, the bonding chamber can be the same as the deposition chamber equipped with the substrate holders that can perform the bonding operation. In some embodiments, a pressure of the bonding chamber can be controlled to maintain top surfaces 165a and 165b to be clean. In some embodiments, a pressing force can be applied to the first and second substrates 110 and 170 once they are stacked with each other. In some embodiments, a temperature of first and second substrates 110 and 170 during the bonding process can be maintained between about 260° C. and about 600° C. In some embodiments, bonding layers 164a and 164b can be pretreated prior to the bonding process, for example, by rinsing bonding layers 164a and 164b in deionized water to form Ti—OH dangling bonds on top surfaces 165a and 165b of bonding layers 164a and 164b. Ti—OH dangling bonds on top surfaces 165a and 165b can promote the bonding strength of bonding layers 164a and 164b at interface 161. In some embodiments, bonding layers 164a and 164b can be pretreated by exposing top surfaces 165a and 165b to a plasma (e.g., an argon plasma or a N₂ plasma) to activate top surfaces 165a and 165b. In some embodiments, the N₂ plasma activation may not be necessary.

Referring to FIG. 3, method 300 continues with operation 340, in which the bonded structure is post-treated in an annealing process, as described with reference to FIGS. 6 and 1A, according to some embodiments.

In some embodiments, the annealing process can be performed by heating up bonded structure 100 in the bonding chamber from the substrate, or by passing heated inert gas 680 in the environment of bonded structure 100. In some embodiments, the annealing process can last for a duration between about 1 minute and about 12 hours at a temperature between about 260° C. and about 600° C. In some embodiments, the annealing process performed in the above conditions can reduce the amount of defects at interface 161 generated during the bonding process. In some embodiments, the annealing process performed in the above conditions can promote a phase transition of TiNₓ in bonding structure 160 from amorphous to FCC, which can improve the thermal conductivity and the bonding strength of bonding structure 160. In some embodiments, the annealing process performed in the above conditions can promote a phase transition of TiOₓ in bonding structure 160 from amorphous to anatase, which can improve the thermal conductivity and the bonding strength of bonding structure 160. In some embodiments, after the phase transition of TiOₓ, interface 161 can become physically indistinguishable since the crystallization of TiOₓ can merge bonding layers 164a and 164b into the single bonding layer 164, as shown in FIGS. 1A, 2A, and 2B.

Method 300 described with reference to FIGS. 3-6 can apply to wafer bonding processes for more than two substrates. For example, while surface 170s of second substrate 170 is bonded with substrate 110 by bonding structure 160, another surface 170t of second substrate 170 can also be bonded, using method 300, to a substrate similar to or different from first substrate 110 by another bonding structure the same as or similar to bonding structure 160. In some embodiments, second substrate 170 can also include semiconductor devices and interconnect structures similar to those in first substrate 110. In some embodiments, a bottom surface 110b of first substrate 110 can also be bonded, using method 300, to a substrate similar or different from first substrate 110, by another bonding structure the same as or similar to bonding structure 160. In some embodiments, using method 300, a number of substrates (such as 3, 4, 5, 8, or 10 substrates) the same as or similar to first substrate 110 can be bonded together as a stack (such as bonded structure 100′ as shown in FIG. 1B) by a number of bonding structures, each being between adjacent substrates and being the same as or similar to bonding structure 160.

Various embodiments in the present disclosure provide examples of a bonded semiconductor structure and a method of forming the bonded semiconductor structure. The bonded semiconductor structure includes first and second substrates bonded by a bonding structure. The bonding structure provides high thermal conductivity and high bonding strength between the first and second substrates. The bonding structure includes bonding layers and adhesion layers, with the bonding layers including titanium oxide and the adhesion layers including titanium nitride. The method includes forming a first adhesion layer on the first substrate and a second adhesion layer on the second substrate. The method also includes forming a first bonding layer on the first adhesion layer and a second bonding layer on the second adhesion layer. The method further includes bonding the first and second substrates by bonding the first and second bonding layers together.

In some embodiments, a method includes forming a first adhesion layer on a first substrate, forming a first bonding layer on the first adhesion layer, forming a second adhesion layer on a second substrate, and forming a second bonding layer on the second adhesion layer. The first and second bonding layers include titanium oxide. The method further includes bonding the first and second substrates by stacking the first and second bonding layers together.

In some embodiments, a method includes forming a first titanium-based bilayer on a substrate and forming a second titanium-based bilayer on a carrier substrate. The first and second titanium-based bilayers include a layer of titanium nitride and a layer of titanium oxide. The method further includes bonding the substrate and the carrier substrate by stacking the first and second layers of titanium oxide together.

In some embodiments, a structure includes a device layer on a first substrate, a dielectric layer on the device layer, a stack of titanium-based bilayers on the dielectric layer, and a second substrate on the stack of titanium-based bilayers. Each of the titanium-based bilayers includes a layer of titanium nitride and a layer of titanium oxide layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first adhesion layer on a first substrate;
forming a first bonding layer on the first adhesion layer, wherein the first bonding layer comprises titanium oxide;
forming a second adhesion layer on a second substrate;
forming a second bonding layer on the second adhesion layer, wherein the second bonding layer comprises titanium oxide; and
bonding the first and second substrates by stacking the first and second bonding layers together.

2. The method of claim 1, wherein bonding the first and second substrates comprises annealing the first and second bonding layers after stacking the first and second bonding layers.

3. The method of claim 2, wherein annealing the first and second bonding layers comprises annealing the first and second bonding layers for a time between about 1 minute and about 12 hours and at a temperature greater than about 260° C.

4. The method of claim 1, wherein forming the first adhesion layer and forming the second adhesion layer comprise depositing titanium nitride simultaneously on the first and second substrates.

5. The method of claim 1, wherein bonding the first and second substrates comprises transforming a crystal structure of the first and second bonding layers from amorphous to anatase.

6. The method of claim 1, wherein bonding the first and second substrates comprises transforming a crystal structure of the first and second adhesion layers from amorphous to face-centered cubic.

7. A method, comprising:
forming a first titanium-based bilayer on a substrate, wherein the first titanium-based bilayer comprises a first layer of titanium nitride and a first layer of titanium oxide;
forming a second titanium-based bilayer on a carrier substrate, wherein the second titanium-based bilayer comprises a second layer of titanium nitride and a second layer of titanium oxide; and
bonding the substrate and the carrier substrate by stacking the first and second layers of titanium oxide together.

8. The method of claim 7, wherein:
forming the first titanium-based bilayer comprises depositing the first layer of titanium nitride on the substrate and depositing the first layer of titanium oxide on the first layer of titanium nitride; and
forming the second titanium-based bilayer comprises depositing the second layer of titanium nitride on the carrier substrate and depositing the second layer of titanium oxide on the second layer of titanium nitride.

9. The method of claim 7, wherein forming the first titanium-based bilayer and forming the second titanium-based bilayer comprise:
simultaneously depositing the first and second layers of titanium nitride; and
simultaneously depositing the first and second layers of titanium oxide.

10. The method of claim 7, wherein forming the first titanium-based bilayer and forming the second titanium-based bilayer comprise depositing the first and second layers of titanium nitride and the first and second layers of titanium oxide at a temperature between about 70° C. and about 250° C.

11. The method of claim 7, wherein forming the first titanium-based bilayer and forming the second titanium-based bilayer comprise depositing the first and second layers of titanium nitride and the first and second layers of titanium oxide in an amorphous form.

12. The method of claim 7, further comprising forming a third titanium-based bilayer on the substrate and under the first titanium-based bilayer.

13. A structure, comprising:
a device layer on a first substrate;
a dielectric layer on the device layer;
a stack of titanium-based bilayers on the dielectric layer, wherein each of the titanium-based bilayers comprises a layer of titanium nitride and a layer of titanium oxide; and
a second substrate on the stack of titanium-based bilayers.

14. The structure of claim 13, wherein a thermal conductivity of the stack of titanium-based bilayers is greater than a thermal conductivity of the dielectric layer.

15. The structure of claim 13, wherein a ratio of a thickness of the layer of titanium nitride to a thickness of the layer of titanium oxide is between about 0.2 and about 0.8.

16. The structure of claim 13, wherein:
a thickness of the layer of titanium nitride is between about 5 nm and about 15 nm; and
a thickness of the layer of titanium oxide is between about 10 nm and about 80 nm.

17. The structure of claim 13, wherein:
a crystal structure of the layer of titanium oxide is anatase; and
a crystal structure of the layer of titanium nitride is face-centered cubic.

18. The structure of claim 13, wherein:
a thermal conductivity of the layer of titanium oxide is between about 5 W/m·K and about 10 W/m·K; and
a thermal conductivity of the layer of titanium nitride is between about 20 W/m·K and about 30 W/m·K.

19. The structure of claim 13, wherein:
a topmost layer of titanium nitride is in contact with the second substrate; and
a bottommost layer of titanium nitride is in contact with the first substrate.

20. The structure of claim 13, wherein a ratio of a thickness of a topmost layer of titanium oxide in the stack of titanium-based bilayers to a thickness of other layers of titanium oxide in the stack of titanium-based bilayers is about 2:1.
